(19) United States
(12) Patent Application Publication
(10) Pub. No.: US 2026/0215311 A1
(43) Pub. Date: Jul. 23, 2026

(54) CIRCUIT BOARD AND SEMICONDUCTOR PACKAGE INCLUDING THE SAME

(71) Applicant: LG INNOTEK CO., LTD., Seoul (KR)

(72) Inventors: Han Sang KIM, Seoul (KR); Kyung Ah WON, Seoul (KR); Bo Ra KANG, Seoul (KR); Inhwan CHA, Seoul (KR); Eung Ryong KIM, Seoul (KR); Ho Sang KWACK, Seoul (KR)

(73) Assignee: LG INNOTEK CO., LTD., Seoul (KR)

(21) Appl. No.: 19/440,328

(22) Filed: Jan. 5, 2026

(30) Foreign Application Priority Data
Jan. 20, 2025 (KR) 10-2025-0007878

(51) Int. Cl. H10W 70/692; H10W 70/63

(52) U.S. Cl. CPC H10W 70/692; H10W 70/635

(57) ABSTRACT

Embodiments of the present disclosure disclose a circuit board including: a glass core layer; a core electrode portion disposed on the glass core layer; a build-up insulating portion disposed on the glass core layer; and a build-up line portion disposed on the build-up insulating portion, wherein the core electrode portion includes a first layer that is in contact with the glass core layer and a second layer disposed on the first layer, and in the second layer, a density of a (111) plane is greater than a density of a (001) plane based on a plane perpendicular to a thickness direction.

### CROSS-REFERENCE TO RELATED APPLICATION

This application claims priority to and the benefit of Korean Patent Application No. 10-2025-0007878, filed on Jan. 20, 2025, the disclosure of which is incorporated herein by reference in its entirety.

### BACKGROUND

### 1. Field of the Invention

Embodiments according to the present disclosure relate to a circuit board and a semiconductor package.

### 2. Discussion of Related Art

As the performance of electrical/electronic products advances, technologies for attaching a greater number of packages to a substrate with a limited size are being proposed and studied. However, since a typical package is based on mounting a single semiconductor chip, there are limits to acquiring the desired performance.

A typical circuit board or package substrate has a form in which a processor package having a processor chip disposed thereon and a memory package having a memory chip attached thereto are connected as one. The package substrate has an advantage in that a mounting area of the chip is reduced and high-speed signal transmission is possible through a short path by manufacturing the processor chip and the memory chip as a single integrated package. Due to this advantage, the above package substrate is widely used in a mobile device and the like.

Meanwhile, recently, the size of a package is increasing due to advancements in specifications of an electronic device such as a mobile device, adoption of a high bandwidth memory (HBM), and the like. Further, as the functionality required in an application processor increases, a separate processor chip is configured for each function, and a circuit board capable of mounting these processor chips thereon is required. In this case, even when the application processor is divided into two processor chips for each function, the number of terminals (input/output) provided on each processor chip is increasing.

Further, recently, as power and the number of signals increase due to 5G, Internet of Things (IOT), an increase in image quality, an increase in communication speed, and the like, the number of terminals on the processor chip is gradually increasing. Accordingly, the area and thickness of a circuit board and the density of a circuit pattern are increasing. When the area and thickness of the circuit board increase, there are problems such as a difficulty in miniaturization of the product, reliability issues such as warpage or the like of the circuit board, an increased product price, and the like. Accordingly, increasing the density of the circuit pattern rather than increasing the area and thickness of the circuit board is more advantageous in terms of product price, reliability issues such as warpage or the like, and product miniaturization. Accordingly, refinement of the circuit pattern or a through hole electrode is required.

Particularly, as the circuit board becomes increasingly thinner, deformation such as warpage, twisting, and the like which occur when manufacturing the circuit board become more severe. In order to prevent this, a glass core structure in which a glass plate is formed in a core portion of the circuit board is being proposed.

However, when the core portion is a glass plate, there is a problem that adhesion and reliability between the glass plate and other electrode portions deteriorate. Further, when a highly adhesive insulating layer or adhesive layer is first formed between the core portion and the electrode portions, there is a problem that it is difficult to protect the glass core layer from external impacts due to the high coefficient of thermal expansion of the insulating layer. Specifically, deterioration in adhesion between the glass core layer and the electrode portions is further increased when forming finely patterned electrode portions.

### SUMMARY OF THE INVENTION

An embodiment of the present disclosure implements a circuit board whose stress is relatively reduced even when having a certain thickness on an amorphous glass core layer by forming a core electrode portion having a high density of an orientation plane which significantly enhances a grain size without an additional insulating layer or adhesive layer between the glass core layer and the core electrode portion, and a semiconductor package including the same.

Further, the embodiment may implement a circuit board having increased flexibility and reduced resistance and thus having improved mechanical and electrical reliability by having a large grain size and higher densities of (111) and (101) orientation planes than a (001) orientation plane, and a semiconductor package including the same.

In addition, the embodiment may implement a circuit board with relatively enhanced reliability of a glass substrate through stress relaxation by forming a core electrode portion on a glass core layer under different conditions from the formation of a build-up line portion to provide a core electrode portion having an orientation plane density and a grain size different from the build-up line portion, and a semiconductor package including the same.

The problems to be solved in the embodiment are not limited thereto, and may also include purposes or effects which may be understood from the solution or embodiment of the problems described below.

A circuit board according to an embodiment of the present disclosure includes: a glass core layer; a core electrode portion disposed on the glass core layer; a build-up insulating portion disposed on the glass core layer; and a build-up line portion disposed on the build-up insulating portion, wherein the core electrode portion includes a first layer that is in contact with the glass core layer and a second layer disposed on the first layer, and in the second layer, a density of a (111) plane is greater than a density of a (001) plane based on a plane perpendicular to a thickness direction.

The first layer may contain a metal oxide.

A thickness of the first layer may be smaller than a thickness of the second layer.

In the second layer, a density of a (101) plane may be greater than the density of the (001) plane based on the plane perpendicular to the thickness direction.

A density of the (111) plane based on a plane perpendicular to a thickness direction of the build-up line portion may be less than the density of the (111) plane based on the plane perpendicular to the thickness direction of the second layer.

A density of a (101) plane based on a plane perpendicular to a thickness direction of the build-up line portion may be less than a density of the (101) plane based on the plane perpendicular to the thickness direction of the second layer.

A density of the (001) plane based on a plane perpendicular to a thickness direction of the build-up line portion may be greater than the density of the (001) plane based on the plane perpendicular to the thickness direction of the second layer.

An average grain size of the build-up line portion may be smaller than an average grain size of the second layer.

An average grain size of the second layer may be greater than 1.9 μm.

The core electrode portion may include a core line portion disposed on an upper surface and a lower surface of the glass core layer and a core via electrode passing through the glass core layer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other objects, features and advantages of the present invention will become more apparent to those of ordinary skill in the art by describing exemplary embodiments thereof in detail with reference to the accompanying drawings, in which:

FIG. 1 is a plan view of a circuit board according to an embodiment of the present disclosure;

FIG. 2 is a view taken along line AA′ in FIG. 1;

FIG. 3 is an enlarged view of portion K1 in FIG. 2;

FIG. 4 is an enlarged view of portion K2 in FIG. 2;

FIG. 5 is an inverse pole figure (IPF) plot by electron backscatter diffraction (EBSD) analysis of a core electrode portion in the circuit board according to the embodiment;

FIG. 6 is a graph showing an inverse pole figure (IPF) map and grain distribution results by electron backscatter diffraction (EBSD) analysis of the core electrode portion in the circuit board according to the embodiment;

FIG. 7 is a result of X-ray diffraction (XRD) analysis of the core electrode portion in the circuit board according to the embodiment;

FIG. 8 is an inverse pole figure (IPF) map by electron backscatter diffraction (EBSD) analysis of the core electrode portion in the circuit board under conditions 1 to 3;

FIG. 9 is an inverse pole figure (IPF) plot by electron backscatter diffraction (EBSD) analysis of the core electrode portion in the circuit board under conditions 1 to 3;

FIG. 10 is a graph showing the grain distribution results for the core electrode portion of the circuit board under conditions 1 to 3;

FIG. 11 is a photograph showing defects in the core electrode portion and core layer of the circuit board under condition 1;

FIGS. 12 to 17 are views for describing a method of manufacturing the circuit board according to the embodiment;

FIG. 18 is a cross-sectional view of a semiconductor package according to a first embodiment;

FIG. 19 is a cross-sectional view of a semiconductor package according to a second embodiment;

FIG. 20 is a cross-sectional view of a semiconductor package according to a third embodiment; and

FIG. 21 is a cross-sectional view of a semiconductor package according to a fourth embodiment.

### DETAILED DESCRIPTION OF EXEMPLARY EMBODIMENTS

Since the present disclosure may be subjected to various changes and have various embodiments, specific embodiments will be exemplified and described in the drawings. However, it should be understood that this is not intended to limit the present disclosure to specific embodiments, and includes all changes, equivalents, and substitutes included in the spirit and scope of the present disclosure.

Hereinafter, preferable embodiments of the present disclosure will be described in detail with reference to the accompanying drawings.

However, the technical spirit of the present disclosure is not limited to some embodiments which will be described and may be embodied in various forms, and one or more elements in the embodiments may be selectively combined, replaced, and used within the scope of the technical spirit of the present disclosure.

Further, terms used in the embodiments of the present disclosure (including technical and scientific terms), may be interpreted with meanings that are generally understood by those skilled in the art unless particularly defined and described, and terms which are generally used, such as terms defined in dictionaries, may be understood in consideration of their contextual meanings in the related art.

In addition, terms used in the description are provided not to limit the present disclosure but to describe the embodiments. In the specification, the singular form may also include the plural form unless the context clearly indicates otherwise and may include one or more of all possible combinations of A, B, and C when disclosed as at least one (or one or more) of “A, B, and C.”

Terms including ordinal numbers, such as second, first, and the like, may be used to describe various components, but the components are not limited by the terms. The terms are used only for the purpose of distinguishing one component from other components. For example, without departing from the scope of the present disclosure, a second component may be referred to as a first component, and similarly, a first component may also be referred to as a second component. The term ‘and/or’ includes any combination of a plurality of related listed items or any one item of the plurality of related listed items. These terms are not used to define the nature, order, or sequence of a corresponding component but merely to distinguish the corresponding component from other component(s).

Further, when a specific component is disclosed as being ‘connected,’ ‘coupled,’ or ‘linked’ to another component, this may not only include a case of the component being directly connected, coupled, or linked to the other component but also a case of the component being ‘connected,’ ‘coupled,’ or ‘linked’ to the other component by another component between the component and the other component.

The terms used in the present application are only used to describe specific embodiments and are not intended to limit the present disclosure. The singular form includes the plural form unless the context clearly indicates otherwise. In the present application, it should be understood that terms such as “include” or “have” are intended to indicate the presence of a feature, number, step, operation, component, part, or a combination thereof described in the specification, and they do not exclude in advance the possibility of the presence or addition of one or more other features, numbers, steps, operations, components, parts or combinations thereof.

Further, when one component is described as being formed “on or under” another component, the term “on or under” includes both a case in which the two components are in direct contact with each other and a case in which at least another component is disposed between the two components (indirect contact). In addition, when the term “on or under” is expressed, a meaning of not only an upward direction but also a downward direction may be included based on one component.

In addition, the expression “configuration A is disposed between configurations B and C” should also encompass a meaning that configuration A is disposed so that configurations B and C at least partially overlap each other in a horizontal direction and/or a vertical direction.

Expressions referring to directions include horizontal and vertical directions, and the horizontal direction includes a first horizontal direction and a second horizontal direction perpendicular to the first horizontal direction. These are referred to as a first horizontal direction (an X-axis), a second horizontal direction (a Y-axis), and a vertical direction (a Z-axis) in the Cartesian coordinate system, and the meaning of overlapping along the horizontal direction should include the meaning of overlapping along the first horizontal direction and/or overlapping along the second horizontal direction.

Further, “configuration A is exposed from configuration B” should be understood to mean that configuration A is exposed not from the entire product but from configuration B. That is, when configuration A is described as being exposed from configuration B, it should be understood to mean that configuration A is at least partially covered by configuration C.

Further, when configuration A is described as being ‘in contact’ with configuration B, it may include not only a case in which the component is directly “in contact” with another component, but also a case in which the component is ‘in contact’ with another component with still another component between the component and another component. Accordingly, when configuration A is to be understood only as being ‘in direct contact’ with configuration B, configuration A is described as being ‘in direct contact’ with configuration B.

Further, when configuration A is described as being ‘covered’ by configuration B, it should be understood that configuration A is covered by configuration B and thus a portion for a function and a purpose to be achieved is covered, and should be understood that configuration A is entirely covered by configuration B unless otherwise indicated.

Unless otherwise defined, all terms used herein, including technical or scientific terms, have the same meaning as terms generally understood by those skilled in the art. Terms such as terms defined in generally used dictionaries should be interpreted as terms having meanings consistent with their meanings in the context of the related art, and should not be interpreted in an idealistic or excessively formal sense unless explicitly defined in the present application.

Before describing the embodiments, an electronic device to which a circuit board and a semiconductor package of the embodiment are applied will be briefly described. The electronic device includes a main board (not shown). The main board may be physically and/or electrically connected to various components. For example, the main board may be connected to the semiconductor package in the embodiment. The semiconductor package may include a circuit board and semiconductor elements, and the semiconductor elements may be mounted on the circuit board.

The semiconductor elements may include active elements and/or passive elements. The active elements may be semiconductor chips in the form of integrated circuits (IC) in which hundreds to millions of elements are integrated into a single chip. The semiconductor chip may be a logic chip, a memory chip, or the like. The logic chip may be a non-memory chip such as a central processor (CPU), a graphics processor (GPU), a field programmable gate array (FPGA), or the like. For example, the logic chip may be an application processor (AP) chip including at least one of a CPU, a GPU, a digital signal processor, a cryptographic processor, a microprocessor, and a microcontroller, an analog-to-digital converter, an application-specific IC (ASIC), or the like, or a chip set including a specific combination of the above-described components.

The memory chip may be a stacked memory such as a high bandwidth memory (HBM). Further, the memory chip may include a memory chip such as a volatile memory (for example, a dynamic random access memory (DRAM)), a non-volatile memory (for example, a read only memory (ROM)), a flash memory, or the like.

Meanwhile, a product group to which the semiconductor package of the embodiment is applied may be any one of a chip scale package (CSP), a flip chip-chip scale package (FC-CSP), a flip chip ball grid array (FC-BGA), a package on package (POP), and a system in package (SIP), but is not limited thereto.

Further, the electronic device may be a smartphone, a personal digital assistant, a digital video camera, a digital still camera, a vehicle, a high-performance server, a network system, a computer, a monitor, a tablet, a laptop, a netbook, a television, a video game, a smart watch, an automotive, or the like. However, the present disclosure is not limited thereto, and of course, the electronic device may also be any other electronic device which processes data.

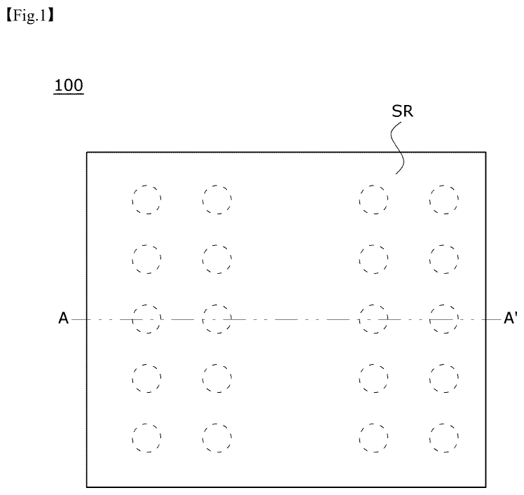

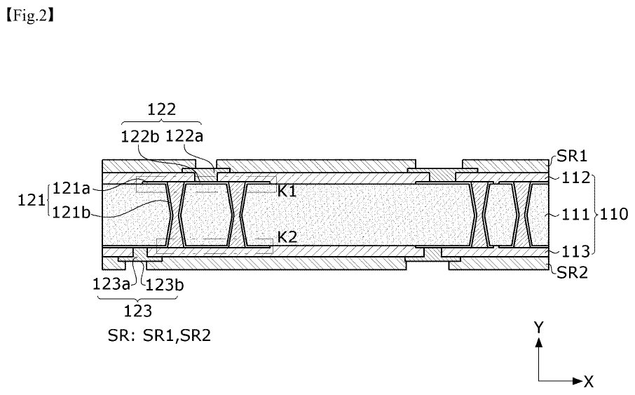

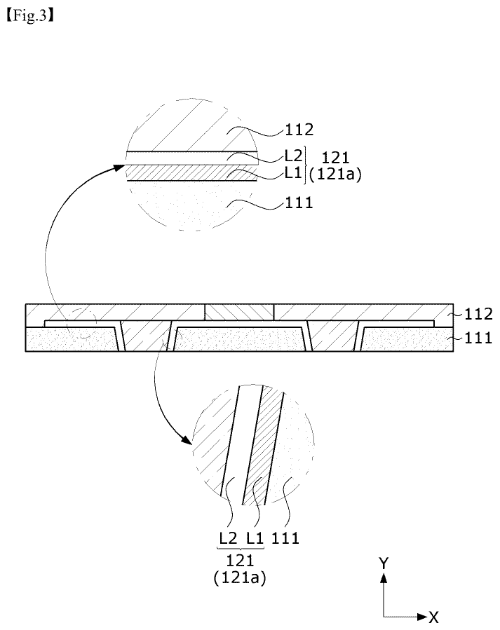

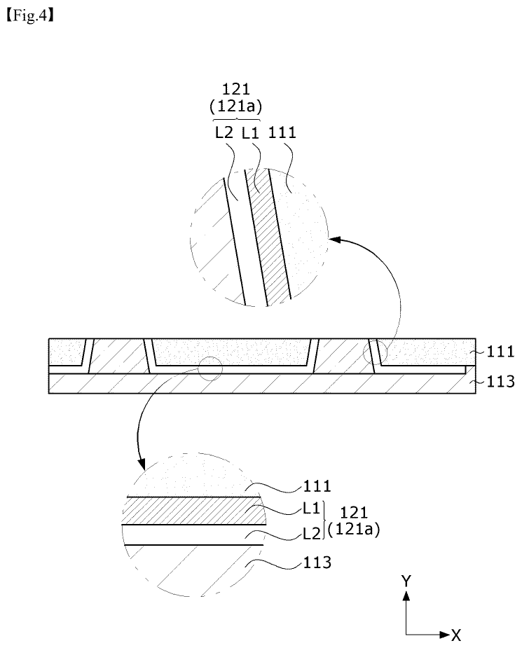

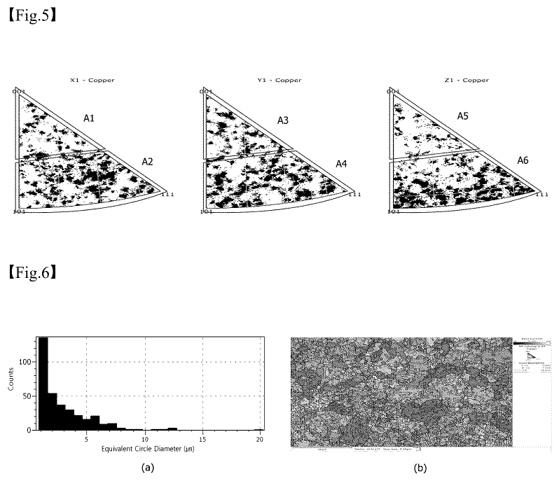

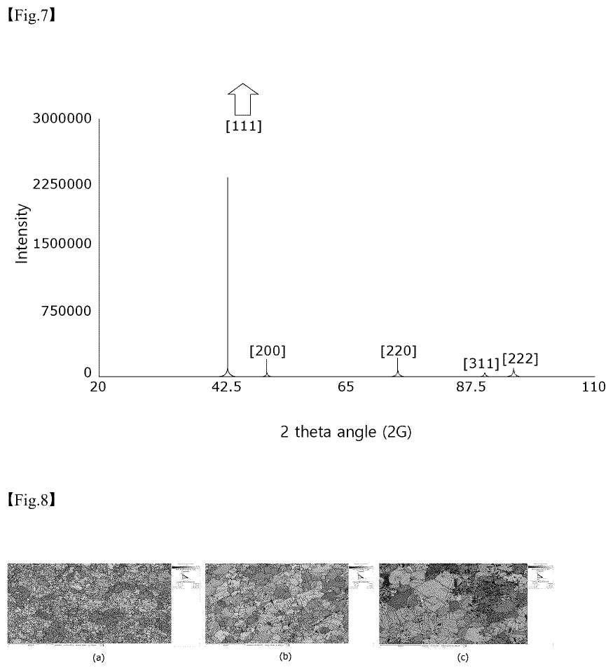

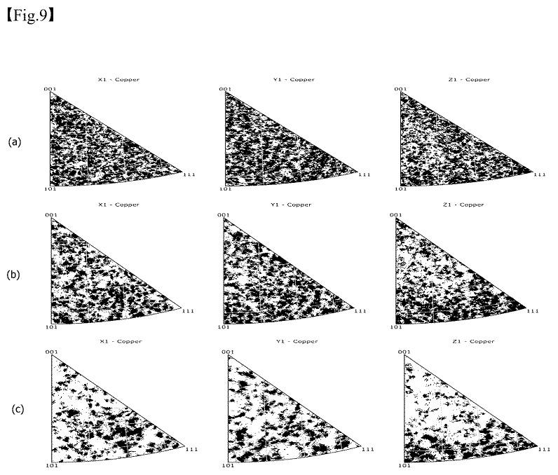

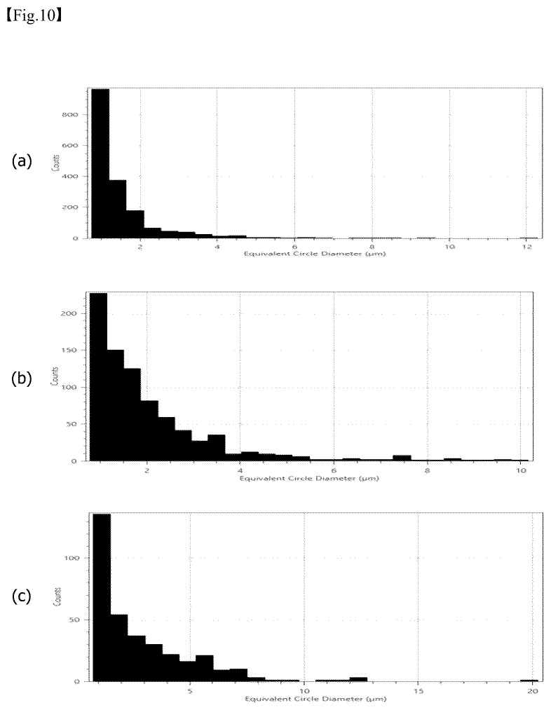

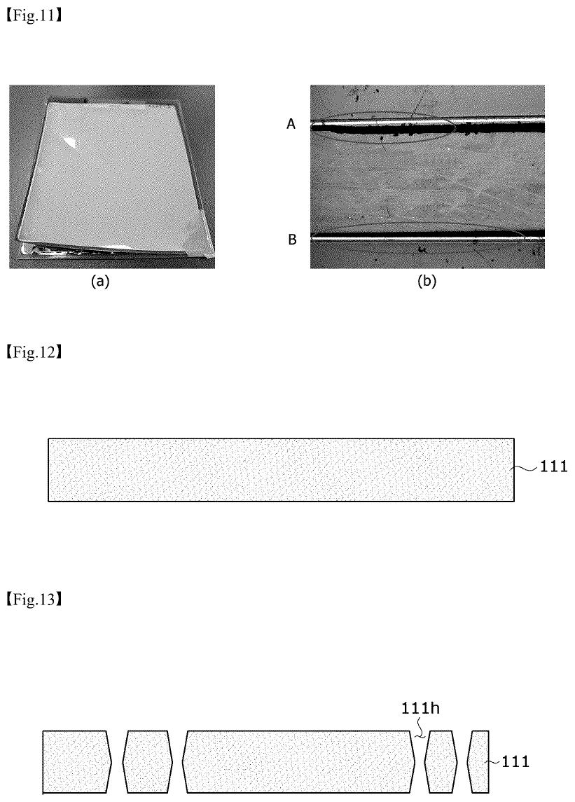

FIG. 1 is a plan view of a circuit board according to an embodiment of the present disclosure, FIG. 2 is a view taken along line AA′ in FIG. 1, FIG. 3 is an enlarged view of portion K1 in FIG. 2, FIG. 4 is an enlarged view of portion K2 in FIG. 2, FIG. 5 is an inverse pole figure (IPF) plot by electron backscatter diffraction (EBSD) analysis of a core electrode portion in the circuit board according to the embodiment, FIG. 6 is a graph showing an inverse pole figure (IPF) map and grain distribution results by electron backscatter diffraction (EBSD) analysis of the core electrode portion in the circuit board according to the embodiment, FIG. 7 is a result of X-ray diffraction (XRD) analysis of the core electrode portion in the circuit board according to the embodiment, FIG. 8 is an inverse pole figure (IPF) map by electron backscatter diffraction (EBSD) analysis of the core electrode portion in the circuit board under conditions 1 to 3, FIG. 9 is an inverse pole figure (IPF) plot by electron backscatter diffraction (EBSD) analysis of the core electrode portion in the circuit board under conditions 1 to 3, FIG. 10 is a graph showing the grain distribution results for the core electrode portion of the circuit board under conditions 1 to 3, and FIG. 11 is a photograph showing defects in the core electrode portion and core layer of the circuit board under condition 1.

Referring to FIGS. 1 and 2, a circuit board 100 according to the embodiment may include an insulating portion 110 and an electrode portion 120. In the embodiment, the insulating portion 110 may be provided in a structure in which a plurality of insulating layers are stacked. The electrode portion 120 may be disposed to be embedded in each insulating layer in a plurality of insulating portions 110, and thus may function to transmit signals and/or power from a main board (not shown) to semiconductor elements.

Further, the circuit board 100 may include a protective layer SR and a build-up structure. The build-up structure may include a build-up insulating portion and a build-up line portion. Further, the build-up structure may include a core portion including a glass core layer 111 and a core electrode portion 121. In addition, the build-up insulating portion may be formed of a plurality of build-up layers. For example, when the circuit board includes a core layer, build-up insulating portions 112 and 113 may include an upper build-up insulating portion 112 and a lower build-up insulating portion 113 as in the embodiment. Specifically, in the embodiment, the circuit board may include the upper build-up insulating portion 112 disposed on an upper surface of the core layer and the lower build-up insulating portion 113 disposed on a lower surface of the core layer. Specifically, as shown, the circuit board 100 may include the glass core layer 111, the build-up insulating portions 112 and 113, the core electrode portion 121, and build-up line portions 122 and 123. Furthermore, the circuit board 100 may further include the protective layer SR disposed on an upper surface of the upper build-up insulating portion and/or a lower surface of the lower build-up insulating portion. Further, in the embodiment of the present disclosure described below, the upper and/or lower build-up insulating portions 112 and 113 may include a plurality of insulating layers stacked along a vertical direction. The build-up line portions 122 and 123 may be disposed to be embedded in each layer (for example, an insulating layer) of the build-up insulating portions 112 and 113, and thus may function to transmit signals and/or power from the main board (not shown) to the semiconductor elements. The build-up line portions 122 and 123 may include circuit layers and via electrodes. The circuit layer may be disposed on one surface of each of the plurality of insulating layers included in the upper and/or lower build-up insulating portions and thus may function to transmit signals and/or power, and the via electrode may pass through at least a portion of each of the plurality of insulating layers to electrically connect the circuit layers to each other. Further, the circuit layer may include a bonding portion (not shown) disposed on the build-up insulating portion to electrically connect the semiconductor elements and/or electronic elements to the circuit board.

The insulating portion 110 of the circuit board, or each insulating layer forming the insulating portion 110, may include chemically strengthened glass/semi-strengthened glass such as soda lime glass, aluminosilicate glass, or the like. For example, the insulating portion 110 of the circuit board may contain a reinforced or flexible plastic such as polyimide (PI), polyethylene terephthalate (PET), propylene glycol (PPG), polycarbonate (PC), or the like. For example, the insulating portion 110 of the circuit board may include sapphire. For example, the insulating portion 110 of the circuit board may include an optically isotropic film. For example, the insulating portion 110 of the circuit board may contain a cyclic olefin copolymer (COC), a cyclic olefin polymer (COP), optically isotropic polycarbonate (PC), or optically isotropic polymethyl methacrylate (PMMA). For example, the insulating portion 110 of the circuit board may be formed of a material including a filler and an insulating resin. For example, the insulating portion 110 of the circuit board may have a structure in which a filler such as silica or alumina is disposed in a thermosetting resin or thermoplastic resin. The insulating portion 110 may have a structure in which a plurality of different insulating materials are stacked, and an exemplary arrangement structure will be described in more detail as follows.

In one embodiment, the insulating portion 110 may include the glass core layer 111 including a reinforcing member.

The glass core layer 111 may be formed of a glass material. For example, the glass core layer 111 may contain pure silicon dioxide (about 100% SiO₂), soda-lime glass, borosilicate glass, aluminosilicate glass, and the like, but is not limited to silicon-based glass compositions, and alternative glass materials, for example, fluoride glass, phosphate glass, chalcogenide glass, and the like may also be used. Further, the glass core layer 111 may further contain other additives to form glass having specific physical properties. These additives may contain calcium carbonate (for example, lime) and sodium carbonate (for example, soda), as well as magnesium, calcium, manganese, aluminum, lead, boron, iron, chromium, potassium, sulfur, and antimony, and carbonates and/or oxides of these and other elements. Further, the glass core layer 111 may contain an insulating material.

The glass core layer 111 may suppress warpage which occurs due to thinning of the circuit board. In other words, warpage may be reduced by disposing a glass layer (or a glass core) with high rigidity and a low coefficient of thermal expansion (CTE) at a center or core of the circuit board. For example, the glass core layer 111 may have high rigidity and a low coefficient of thermal expansion compared to other insulating layers or protective layers.

Further, the upper build-up insulating portion 112 or the lower build-up insulating portion 113 may be formed of an arbitrary insulating resin such as a thermosetting resin and/or a photocurable resin. As the thermosetting resin, an Ajinomoto build-up film (ABF), which is a product released by Ajinomoto, may be used, and a material such as prepreg (PPG) or the like containing glass fiber may be used. As the photocurable resin, an arbitrary insulating resin such as a photo imageable dielectric (PID) resin or the like may be used. The above-described arbitrary insulating resin may be, for example, epoxy resin, bismaleimide triazine resin (BT resin), phenol resin, or the like, and may contain an inorganic filler such as silica or the like. When an insulating resin is used as the core, the insulating resin may include a reinforcing material or reinforcing member composed of glass fiber or aramid fiber. For example, when manufacturing the insulating portion 110, the ABF, which is a product released by Ajinomoto, may be used, and FR-4, bismaleimide triazine (BT), a photo imageable dielectric (PID) resin, BT, or the like may be used. For example, when the circuit board 100 is coreless, the insulating portion 110 may be formed by stacking the ABF without a core layer.

Further, the line or electrode portion 120 according to the embodiment is disposed for electrical connection between the main board or the like and the chip (or a semiconductor element or die), and the electrode portion 120 includes a line portion (a circuit pattern or a circuit pattern layer, a pad, a pattern portion) and a via portion (or via electrode).

For example, the line portion of the electrode portion 120 may include a pattern and a pad on an upper surface of the insulating layer. Hereinafter, the line portion will be used interchangeably with ‘circuit pattern’ and ‘pattern portion’. Further, the electrode portion 120 may include a via portion or via electrode passing through the insulating layer. Accordingly, in the embodiment, the electrode portion 120 will be described below as including a line portion (a circuit pattern) and a via electrode in each insulating layer. Further, the line portion in the electrode portion 120 may be designed in various forms for transmitting signals and/or power to the semiconductor elements, and may be disposed in each insulating layer of the stacked build-up insulating portions 112 and 113.

The via electrode (or via portion) in the electrode portion 120 is disposed to pass through at least a portion of each insulating layer to vertically connect the circuit patterns disposed in each insulating layer of the build-up insulating portions 112 and 113. The via electrode may connect a plurality of circuit patterns (line portions) to each other. Like the line portion, a plurality of via electrodes may be provided. That is, the insulating layer may include via holes for disposing the via electrodes. Further, the via electrode may have a wider width than the circuit pattern for impedance optimization or heat dissipation, but is not limited thereto, and may be freely designed

The line portion (circuit pattern) in the electrode portion 120 may be disposed on each insulating layer. Further, the circuit pattern may be electrically connected to another circuit pattern. In addition, the line portion (circuit pattern) may be connected to each via electrode. In addition, the circuit patterns disposed on an upper surface and a lower surface of each insulating layer in the build-up insulating portions 112 and 113 may be electrically connected to semiconductor elements and/or a main board, a substrate, or the like. For example, the electrode portions 120 may be located in the glass core layer 111 and each of the layers (insulating layers) of the upper build-up insulating portion 112 and the lower build-up insulating portion 113.

Specifically, in the embodiment, the electrode portion 120 may include the core electrode portion 121 and the build-up line portions 122 and 123. The build-up line portions 122 and 123 may include an upper electrode portion 122 and a lower electrode portion 123. The upper electrode portion 122 and the lower electrode portion 123 may be build-up line portions. Further, the upper electrode portion 122 may be disposed on each insulating layer in the upper build-up insulating portion 112 and may be an ‘upper build-up line portion.’ In addition, the lower electrode portion 123 may be disposed on each insulating layer in the lower build-up insulating portion 113 and may be a ‘lower build-up layer electrode portion.’ Alternatively, the electrode portion may include a build-up line portion and a build-up via electrode (a via portion).

The core electrode portion 121 may include a core line portion 121a disposed on an upper surface and a lower surface of the glass core layer 111 and a core via electrode 121b passing through the glass core layer 111.

The upper electrode portion 122 may include an upper line portion 122a which is a line portion disposed on an upper surface and a lower surface of each insulating layer of the upper build-up insulating portion 112, and an upper via electrode 122b which is a via electrode. The upper via electrode 122b may pass through each insulating layer of the upper build-up insulating portion 112.

Furthermore, the lower electrode portion 123 may include a lower line portion 123a which is a line portion disposed on an upper surface and a lower surface of the lower build-up insulating portion 113, and a lower via electrode 123b which is a via electrode. Further, the lower via electrode 123b may pass through each insulating layer of the lower build-up insulating portion 113.

In addition, in the embodiment, the line portion of the upper electrode portion (and/or the lower electrode portion) may include a line portion (a second line portion) having a fine pitch and a line portion (a first line portion) having a pitch greater than that of the second line portion.

The protective layer SR may function to protect the pad from external moisture or contaminants, and in order to prevent short-circuit issues when bonding between the semiconductor elements and/or the main board and the circuit board, for example, the protective layer SR may be formed of a solder resist. Specifically, the semiconductor elements and/or the main board have a plurality of terminals to allow the circuit board to be connected thereto. Further, the plurality of terminals may be disposed with a high density. When the plurality of terminals and pads of the circuit board are bonded, for example, solder may be used. When using solder, since a solder short-circuit issue between terminals with a high density may occur, a solder resist with poor wetting properties with solder may be disposed to address this short-circuit issue. Further, the protective layer SR may be made of a material having electrical insulating properties for electrical connection. The protective layer SR may include a resin, a curing agent, a photoinitiator, a pigment, a solvent, a filler, an additive, an acrylic monomer, or the like. Further, the protective layer SR may include anyone of a photo solder resist layer, a coverlay, and a polymer material. The protective layer SR may have at least one or more openings for connection(s) between the terminals of the semiconductor elements and the pads on the circuit board. For example, in the embodiment, the protective layer SR may be made of a filler, which is a reinforcing member, and a resin.

The protective layer SR may be disposed on the build-up insulating portions 112 and 113. Further, the protective layer SR may include a plurality of fillers. Specifically, the protective layer SR may include a first protective layer SR1 disposed on the upper build-up insulating portion 112 and a second protective layer SR2 disposed under the lower build-up insulating portion 113. The first protective layer SR1 and the second protective layer SR2 may be disposed spaced apart from each other along a stacking direction and may have different thicknesses in consideration of the warpage of the circuit board. Hereinafter, the protective layer will be described based on the first protective layer SR1.

The bonding portion (not shown) may be disposed on the protective layer SR. For example, the bonding portion (not shown) may be disposed on an upper surface of the protective layer SR. The bonding portion (not shown) may be located outside the build-up line portions 122 and 123. For example, in the upper build-up insulating portion 112, the bonding portion (not shown) may be located on the build-up line portions 122 and 123. Further, the bonding portion (not shown) may include a protrusion disposed on the upper surface of the protective layer SR and a via region passing through the protective layer SR. In the embodiment, the via region and the protrusion may each include a plurality of protrusions or convex portions protruding toward the adjacent protective layer SR. For example, on the first protective layer SR1, the via region and the protrusion may include a plurality of protrusions (or convex portions) protruding toward the first protective layer SR1.

Furthermore, the bonding portion (not shown) may include a plurality of metal layers, or additional metal layers may be disposed on the bonding portion. The durability and reliability of the bonding portion (not shown) may be further improved. For example, the bonding portion or the metal layer may be formed of at least one metal layer. The metal layer may be made of copper (Cu), gold (Au), nickel (Ni), palladium (Pd), tungsten (W), titanium (Ti), or a combination thereof. Accordingly, the bonding strength between the metal layer and the bonding portion (not shown) may be improved, the corrosion resistance and durability of the bonding portion (not shown) may be improved, and electrical signal loss may also be minimized. The metal layer may be formed on the bonding portion (not shown) by deposition, electroplating, or the like of various metals.

Further, a semiconductor element may be disposed on the upper build-up insulating portion 112. The semiconductor element may be electrically connected to the second line portion, which is the above-described fine pattern. The circuit board may be disposed to have a high line density for signal connection with the semiconductor elements. Further, the second line portion, which is a fine pattern, may function as a line for signal connection between the semiconductor elements, or may perform signal connection (for example, providing a signal to the lower substrate) for each semiconductor element. Accordingly, it may be provided to prevent the semiconductor elements from becoming unnecessarily large to improve the yield of the semiconductor elements.

Further, the circuit board may be classified into a package substrate and an interposer depending on the function thereof. The package substrate functions to mount semiconductor elements and/or interposers. As an area of the circuit board increases or the stacked number of insulating layers increases due to an increase in data, circuit board yield may significantly deteriorate. Accordingly, in order to improve the yield of circuit boards having a high stacking count, circuit board yield may be improved by separating the circuit board into an interposer and a package substrate. In addition, as the terminal density of the semiconductor element increases, it may be difficult to implement pads on the package substrate having an area corresponding to the terminals of the semiconductor elements. Accordingly, the interposer may serve as a buffer between the pad size of the package substrate and the fine pattern size of the terminal of the semiconductor element.

The above-described package substrate and interposer may be respectively classified into a core substrate and a coreless substrate depending on the composition of the insulating layer as described above. In the case of the core substrate, the insulating layer may include a core layer, and the core layer may mean a layer including a reinforcing member among the stacked insulating layers. The reinforcing member may mean glass fiber. The core layer may be disposed thicker than other insulating layers, and thus may have a function of preventing the circuit board from warping during processing. However, the core layer may cause problems such as voltage drop, signal loss, and the like or make thinning difficult. Accordingly, depending on the application, the insulating layer of the circuit board may use a coreless substrate not including a core layer.

Referring to FIGS. 3 and 4, the core electrode portion 121 may include a first layer L1 which is in contact with the glass core layer and a second layer L2 disposed on the first layer. The core line portion 121a and the core via electrode 121b of the core electrode portion 121 may include the first layer L1 and the second layer L2.

In the embodiment, the first layer L1 may be in contact with the glass core layer 111. No other insulating layer may be present between the first layer L1 and the glass core layer 111. Further, the first layer L1 may contain a metal oxide. For example, the first layer L1 may contain titanium oxide (TiO₂), tin oxide (SnO), or the like.

Further, the second layer L2 may be located on the first layer L1. The second layer L2 may be made of a metal material. For example, the second layer L2 may be in contact with the build-up line portions 122 and 123 and electrically connected to the build-up line portions 122 and 123. In the embodiment, a thickness of the first layer L1 may be smaller than a thickness of the second layer L2. For example, the thickness of the first layer L1 may be 0.2 times or less the thickness of the second layer L2.

Further, in the core electrode portion 121 according to the embodiment, the second layer L2 may have a structure in which a (111) or (101) orientation plane has a higher density than a (001) orientation plane. In the core electrode portion 121, since the second layer L2 has a crystal structure in which the density of the (111) orientation plane is high, a lattice constant difference from the first layer L1 on the amorphous glass core layer 111 may be reduced. Particularly, the second layer L2 may have low surface energy because stress is significantly relaxed by forming a dislocation array and the like on the (111) orientation plane while an average grain size increases due to surface modification through heat treatment. Accordingly, the second layer L2 has high stability at an interface, and thus may provide enhanced stress relaxation. Hereinafter, the descriptions of the EBSD analysis and the like for the core electrode portion 121 are descriptions for the second layer.

Furthermore, in the embodiment, unlike the core electrode portion 121, the build-up line portions 122 and 123 may not have a higher density in the (111) and (101) orientation planes than in the (001) orientation plane. For example, in the embodiment, the density of the (111) and (101) orientation planes in the build-up line portions 122 and 123 may be less than twice the density of the (001) orientation plane. Further, an average grain size in the build-up line portions 122 and 123 may be smaller than a grain size in the core electrode portion 121.

Hereinafter, EBSD analysis results for the core electrode portion 121 will be described based on the drawings described below.

EBSD analysis is a technique which analyzes a crystal structure, a grain orientation, a grain size, a texture, a microstructure, and the like using a scanning electron microscope (SEM).

The EBSD analysis was performed by irradiating an electron beam onto a surface of the core electrode portion 121 on the glass core layer 111 in the circuit board according to the embodiment. The surface of the core electrode portion 121 on the glass core layer 111 may also be polished.

According to the EBSD analysis, when an electron beam is irradiated onto the surface (or upper surface) of the core electrode portion 121, and backscatter electrons (BSE) generated by the electron beam interact with a crystal structure of the core electrode portion to generate a specific diffraction pattern (for example, a Kikuchi pattern), the crystal structure (phase identification) and a grain orientation are identified based on the specific pattern.

Particularly, in the case of the circuit board according to the embodiment, the IPF plot and map were generated using data (for example, a pattern or the like) from the EBSD analysis. Accordingly, it was confirmed in what direction the individual grains in the core electrode portion of the circuit board are arranged.

Here, the IPF plot is a scatter plot showing that a specific direction (the X, Y, or Z direction) in the sample (here, the core electrode portion) is aligned with which direction in the crystal structure. In other words, the IPF plot is a plot which analyzes the frequency of a crystal orientation in the specific direction.

Specifically, in the IPF plot, the X direction indicates how a rolling direction (RD) of the core electrode portion is aligned with the crystal orientation. For example, a case in which a [111] orientation is strongly indicated in the X direction means that the grains are aligned in the [111] direction after rolling. Further, the Y direction in the IPF plot indicates a relationship between a transverse direction (TD) and the crystal orientation of the core electrode portion. For example, whether a specific texture formation is also present in the transverse direction of the sample may be analyzed. The texture indicates a degree to which grains in the sample are aligned in a specific crystal orientation. Accordingly, a random texture means that grain orientations are uniformly distributed, and a strong texture means that most grains are aligned in a specific direction. Furthermore, the orientation plane is a state in which a specific plane of the grain is aligned with a specific orientation of the sample, and the formation of the texture may correspond to the presence of a specific orientation plane. For example, a case in which a (111) texture is strong may mean that many grains have a (111) orientation plane. Furthermore, the orientation plane may be identified using the IPF map.

Further, in the IPF plot, the Z direction represents how a normal direction (ND) of the core electrode portion is aligned with the crystal orientation. For example, generally, the degree to which the surface of the sample (for example, the core electrode portion) is aligned in the specific crystal orientation (for example, [111], [001], or the like) may be analyzed through the texture in the Z direction.

Further, in the IPF plot, each dot represents a single grain. In addition, when dots are concentrated in the specific crystal orientation ([111], [101], or [001]), it is understood that a strong texture is present in the crystal orientation. The texture may correspond to a specific crystal orientation. For example, a case in which the texture is strong in the Z direction means that the specific crystal orientation (for example, [111]) is disposed parallel to the sample surface.

Further, the density of points (data points) in the IPF plot may represent the number of grains aligned in a specific crystal orientation.

The IPF map is a two-dimensional (2D) image in which the crystal orientation of each pixel is expressed as a color after photographing the surface of the sample (here, the core electrode portion) in the EBSD analysis. That is, the IPF map is a color image which visually represents the grain orientation of the sample. Accordingly, each pixel represents an individual grain in the sample. Accordingly, a case in which a specific color is dominant means that texture is formed in the corresponding direction. For example, red may be the [001] direction, green may be the [101] direction, blue may be the [111] direction, and a mixed color may be a grain in which the above directions are combined.

Referring to FIG. 5, comparison of an upper region A1 and a lower region A2 shows that more data points are distributed in the (101) and (111) directions than in the (001) direction in the X direction (RD). Accordingly, in the circuit board according to the embodiment, the core electrode portion does not have a dominant texture in the (001) direction in the X direction (RD), and more texture is formed in the (101) or (111) direction.

Furthermore, comparison of an upper region A3 and a lower region A4 shows a pattern in the Y direction (TD) similar to the distribution pattern in the X direction (RD). That is, in the core electrode portion of the circuit board with more data points in the (101) and (111) directions than in the (001) direction, less texture is formed in the (001) direction and more texture is formed in the (101) and (111) directions even in the transverse direction.

Comparison of an upper region A5 and a lower region A6 shows that more data points are distributed in the (111) direction compared to the (001) and (101) directions in the Z direction (ND). Accordingly, in the circuit board, it can be seen that the core electrode portion is formed with a dominant texture in the (111) direction in the Z direction (ND). Further, in the circuit board, it can be seen that the core electrode portion is formed with a texture that is more dominant in the (101) direction than in the (001) direction in the Z direction (ND). Accordingly, it can be seen that the densities of the (111) and (101) orientation planes are higher than the density of the (001) orientation plane. For example, it can be seen that the density of the (111) orientation plane is the highest and thus the core electrode portion of the circuit board is thermodynamically stable. Particularly, since the core electrode portion has a face-centered cubic (FCC) structure while being recrystallized according to a certain temperature and time, flexibility may be high and resistance may decrease. Accordingly, in the circuit board according to the embodiment, the core electrode portion may effectively implement stress relief with the glass core layer, and thus the reliability of the glass core layer may be improved.

Referring further to FIG. 6A, the average grain size of the second layer may be greater than 1.9 um. Here, the X-axis represents the equivalent circle diameter (μm) of the grain, and indicates grain size. The Y-axis indicates the number of grains having the corresponding size. Specifically, a total of 344 grains were measured, and it was measured that an average grain size (ECD) is 2.9 μm and many smaller grains are present. Further, it was measured that an area-weighted average grain size is 7.3 μm and some large grains are present. In addition, the distribution of the grain sizes was measured to be skewed with the presence of many small grains. Furthermore, the maximum grain size was measured to be 19.9 μm, and the minimum size was measured to be 1.0 μm.

Referring further to FIG. 6B, according to the color distribution, it can be seen that that green and blue are more prevalent than red. Furthermore, the orientation plane for the Z direction (ND) is shown. That is, it can be seen that the (101) and (111) orientation planes have higher densities than the (001) orientation plane. In other words, in the second layer of the core electrode, the density of the (111) plane may be greater than the density of the (001) plane based on a plane perpendicular to the thickness direction. Further, in the second layer, the density of the (101) plane may be greater than the density of the (001) plane.

In addition, referring to FIG. 7, X-ray diffraction (XRD) analysis results for the core electrode portion (for example, the second layer) were measured. The X-ray diffraction analysis may indicate the diffraction intensity for a 2θ (2 theta) diffraction angle and analyze a specific crystal plane (Miller index). Particularly, it can be seen that the strongest diffraction peak appears in the (111) direction, and a diffraction peak order sequentially appears as (111), (200), (220), (311), and (222), indicating that the core electrode portion has an FCC structure. Particularly, it can be seen that the core electrode portion (the second layer) has a high density of (111) orientation planes.

Further, Table 1 below shows conditions 1 to 3. Conditions 1 to 3 are heat treatment conditions, and mean heat treatment conditions of the core electrode portion on the glass core layer. Further, condition 1 corresponds to the core electrode portion of the circuit board according to an experimental example. Particularly, condition 1 may correspond to the build-up line portion. Conditions 2 and 3 correspond to the core electrode portion of the circuit board according to the embodiment.

TABLE 1

| Classification | Heat Treatment Conditions |
|---|---|
| Condition 1 | 150° C., 30 min |
| Condition 2 | 300° C., 30 min |
| Condition 3 | 450° C., 30 min |

Referring to FIGS. 8 to 10, as in conditions 2 and 3, in the core electrode portion (the second layer) of the circuit board according to the embodiment, the density of the (111) plane may be formed greater than the density of the (001) plane based on a plane perpendicular to the thickness direction. Further, in the core electrode portion (the second layer), the density of the (101) plane may be greater than the density of the (001) plane. As in condition 1, in the core electrode portion of the circuit board according to the experimental example, the densities of the (111) and (101) planes may not be greater than the density of the (001) plane.

Accordingly, in the circuit board according to the embodiment, the density of the (111) plane based on a plane perpendicular to a thickness direction of the build-up line portion may be less than the density of the (111) plane based on a plane perpendicular to the thickness direction of the second layer. Further, in the circuit board, the density of the (101) plane based on a plane perpendicular to the thickness direction of the build-up line portion may be less than the density of the (111) plane based on a plane perpendicular to the thickness direction of the second layer.

Further, as in conditions 2 and 3, the core electrode portion (the second layer) of the circuit board according to the embodiment may have an average grain size of 1.9 um or more. On the other hand, the average grain size of build-up line portion may be smaller than 1.9 μm. In this way, the average grain size of the build-up line portion may be smaller than the average grain size of the second layer.

In this way, as stress on the core electrode portion is relaxed by controlling the orientation plane and the average grain size of the core electrode portion as described above, phenomena such as fracture (C) of an intermediate region of the glass core layer, cracks (A), delamination (B) from the core electrode portion, and the like may be suppressed in the glass core layer as shown in FIG. 11. FIG. 11 shows a phenomenon which occurs when the core electrode portion is formed under condition 1. In this way, the bonding strength between the glass core layer and the core electrode portion disposed on the glass core layer may be improved, and the reliability of the circuit board may also be improved.

FIGS. 12 to 17 are views for describing a method of manufacturing the circuit board according to the embodiment.

The same reference numerals are given to the above-described same components, overlapping descriptions of the same components will be omitted, and only differences will be described.

Further, the circuit board according to the embodiment may correspond to a unit circuit board. That is, during a manufacturing process, a mother circuit board may be formed of a plurality of unit circuit boards. The mother circuit board may be separated into the plurality of unit circuit boards along a sawing line. In order to form the mother circuit board, a glass layer may be first disposed. The glass layer (or glass core layer) may be manufactured by various methods. Further, the following description will be based on the manufacturing of a unit circuit board.

The method of manufacturing the circuit board according to the embodiment may include the operations of preparing a glass core layer, forming a first through hole in the glass core layer, forming a core electrode portion on upper and lower surfaces of the glass core layer and an inner side surface of the first through hole, forming an upper build-up insulating portion and a lower build-up insulating portion, forming a build-up line portion, and forming a protective layer, a bonding portion, and the like.

Referring to FIG. 12, a method of manufacturing the glass core layer (or core substrate) in the circuit board according to the embodiment may first include preparing a glass core layer 111 made of glass. The glass core layer 111 may correspond to the above-described glass core layer or core layer.

Referring to FIG. 13, further, a first through hole 111h may be formed in the glass core layer 111. The first through hole 111h may correspond to the above-described via hole. The first through hole 111h may be formed by etching both surfaces of the glass core layer 111. For example, a via electrode may be formed in the via hole or through hole of the glass layer. For example, the first through hole 111h may be formed by a photolithography process using a photomask or various etching methods such as a laser method, and the like.

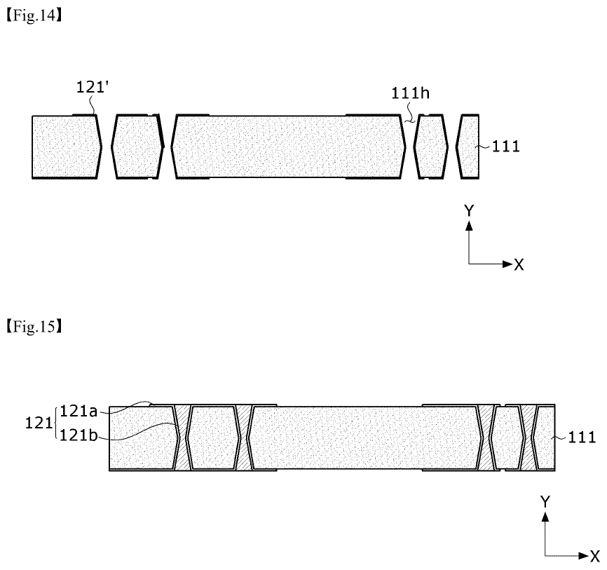

Referring to FIG. 14, a seed layer 121′ of the core electrode portion may be formed on one surface (an upper surface or bottom surface) of the glass core layer 111. For example, the seed layer 121′ of the core electrode portion may be formed on the upper and lower surfaces of the glass core layer 111 and on an inner side wall of the first through hole 111h. For example, a dry method (for example, sputtering), a wet method, or the like may be applied to form the seed layer 121′ of the core electrode portion. Particularly, spin coating, diffusion coating, spray coating, dip coating, CVD, ALD, or the like may be applied here.

Referring to FIG. 15, plating may be performed on the seed layer 121′ of the core electrode portion. The plating on the seed layer 121′ of the core electrode portion may be performed in various ways. Accordingly, a core electrode portion 121 may be formed. For example, the seed layer and the plating layer may be formed by sputtering. The sputtering may be defined as a technology in which an inert element such as argon or the like collides with a target (a metal plate) to expel metal molecules and then deposit a film on the surface. When direct current power is applied to the target while flowing an inert gas as a sputtering gas in a vacuum chamber, plasma may be generated between a substrate to be deposited and the target. Further, the inert gas may be ionized into positive ions in the plasma by a high-power DC ammeter. In this case, the positive ions in the inert gas may be accelerated to a negative electrode by the DC ammeter and may collide with the surface of the target. The target material which collides with the surface of the target in this way may be ejected from the surface by exchanging momentum through a perfectly elastic collisions between atoms. When ions collide with a kinetic energy greater than the interatomic binding energy of the material, atoms in the lattice of the material are pushed to a different position by the ion impact, and in this case, surface escape of the atoms occurs. This phenomenon is called sputtering. In addition, various plating methods described above may be used. Accordingly, the core electrode portion may be formed.

Further, as described above, the core electrode portion may be formed of a first layer and a second layer. The core electrode portion may be recrystallized through heat treatment methods such as conditions 2 and 3 described above. Accordingly, the above-described orientation plane density and average grain size may be achieved.

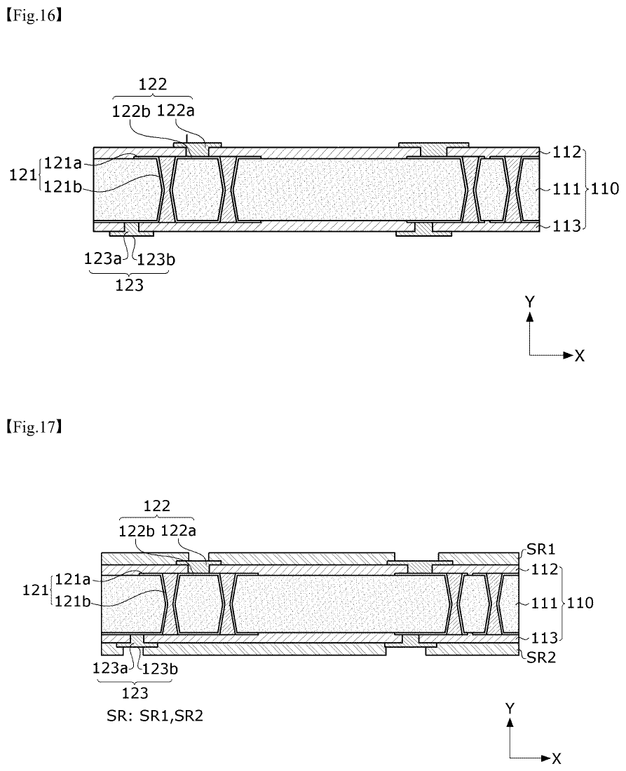

Referring to FIG. 16, after the core electrode portion 121 is formed on the glass core layer 111, an upper build-up insulating portion 112, a lower build-up insulating portion 113, and the like may be further formed. Likewise, a through hole may be formed in each insulating layer, and a build-up line portion may be formed on each insulating layer. The build-up line portion may be formed using a printed circuit board manufacturing process such as an additive process, a subtractive process, a modified semi-additive process (MSAP), a semi-additive process (SAP), or the like.

Referring to FIG. 17, a protective layer may be formed on or under the upper build-up insulating portion 112 and the lower build-up insulating portion 113. In addition, an opening region for a conductive member may be formed in the protective layer.

Furthermore, structures for the above-described various embodiments and modifications may also be equally applied to the circuit board according to the embodiment.

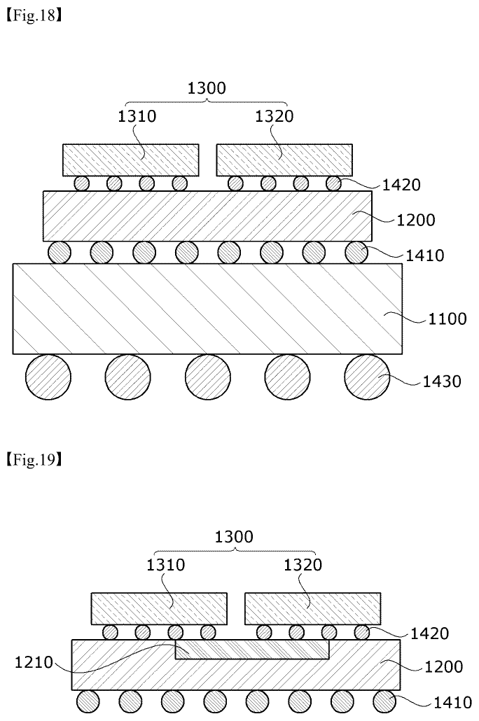

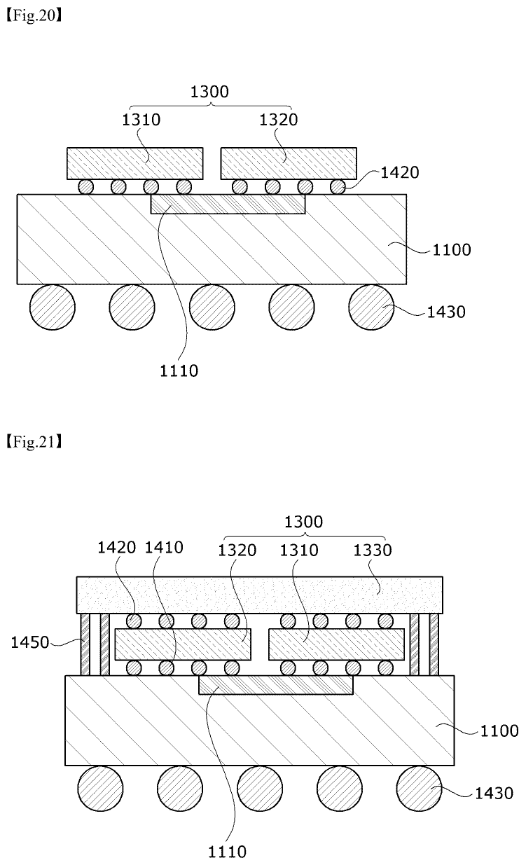

FIG. 18 is a cross-sectional view of a semiconductor package according to a first embodiment, FIG. 19 is a cross-sectional view of a semiconductor package according to a second embodiment, FIG. 20 is a cross-sectional view of a semiconductor package according to a third embodiment, and FIG. 21 is a cross-sectional view of a semiconductor package according to a fourth embodiment.

In the various semiconductor packages described below, the above-described circuit board may be located in a partial region or may correspond to one substrate.

Referring to FIG. 18, the semiconductor package of the first embodiment may include a first substrate 1100, a second substrate 1200, and a semiconductor element 1300.

The first substrate 1100 may mean or include ‘a package substrate,’ ‘a circuit board,’ or the like. For example, the first substrate 1100 may provide a space for at least one external substrate to be coupled. The external substrate may mean the second substrate 1200 coupled to the first substrate 1100. Further, the external substrate may mean a main board included in an electronic device coupled to a lower portion of the first substrate 1100.

In addition, although not shown in the drawing, the first substrate 1100 may provide a space for mounting at least one semiconductor element.

The first substrate 1100 may include at least one insulating layer and an electrode portion disposed on the at least one insulating layer.

The second substrate 1200 may be disposed on the first substrate 1100.

The second substrate 1200 may be an interposer. For example, the second substrate 1200 may provide a space for mounting at least one semiconductor element. The second substrate 1200 may be connected to at least one semiconductor element 1300. For example, the second substrate 1200 may provide a space for mounting a first semiconductor element 1310 and a second semiconductor element 1320. The second substrate 1200 may electrically connect the first and second semiconductor elements 1310 and 1320 and the first substrate 1100 while electrically connecting the first semiconductor element 1310 and the second semiconductor element 1320. That is, the second substrate 1200 may function as a horizontal connection between a plurality of semiconductor elements and a vertical connection between the semiconductor elements and the package substrate.

Further, although the above-described example shows that two semiconductor elements 1310 and 1320 are disposed on the second substrate 1200, the present disclosure is not limited thereto. For example, one semiconductor element may be disposed on the second substrate 1200, or alternatively, three or more semiconductor elements may be disposed on the second substrate 1200.

The second substrate 1200 may be disposed between at least one semiconductor element 1300 and the first substrate 1100.

In one embodiment, the second substrate 1200 may be an active interposer which functions as a semiconductor element. When the second substrate 1200 functions as a semiconductor element, the semiconductor package of the embodiment may have a vertically stacked structure on the first substrate 1100 and may function as a plurality of logic chips. Being capable of functioning as a logic chip may mean being capable of functioning as both active and passive elements. In the case of active elements, the current and voltage characteristics may not be linear unlike passive elements, and the active interposer may function as an active element. Further, the active interposer may perform a signal transmission function between a second logic chip disposed thereon and the first substrate 1100 while functioning as the corresponding logic chip.

According to another embodiment, the second substrate 1200 may be a passive interposer. For example, the second substrate 1200 may function as a signal relay between the semiconductor element 1300 and the first substrate 1100, and may function as a passive element such as a resistor, a capacitor, an inductor, or the like. For example, the number of terminals in the semiconductor element 1300 is gradually increasing due to factors such as 5G, the Internet of Things (IoT), an increase in image quality, an increase in communication speed, and the like. That is, the number of terminals in the semiconductor element 1300 is increasing, and accordingly, widths of the terminals or intervals between the terminals are decreasing. In this case, the first substrate 1100 may be connected to the main board of the electronic device. Accordingly, in order for the electrodes provided on the first substrate 1100 to have a width and an interval to be connected to each of the semiconductor element 1300 and the main board, there is a problem that a thickness of the first substrate 1100 increases or a layer structure of the first substrate 1100 becomes complicated. Accordingly, in the first embodiment, the second substrate 1200 may be disposed on the first substrate 1100 and the semiconductor element 1300. Further, the second substrate 1200 may include electrodes having a fine width and interval corresponding to the terminals of the semiconductor element 1300.

The semiconductor element 1300 may be a logic chip, a memory chip, or the like. The logic chip may be a CPU, a GPU, or the like. The memory chip may be a stacked memory such as a HBM or the like.

Meanwhile, the semiconductor package of the first embodiment may include a connection portion.

For example, the semiconductor package may include a first connection portion 1410 disposed between the first substrate 1100 and the second substrate 1200. The first connection portion 1410 may electrically connect the first substrate 1100 and the second substrate 1200 while bonding the second substrate 1200 to the first substrate 1100.

For example, the semiconductor package may include a second connection portion 1420 disposed between the second substrate 1200 and the semiconductor element 1300. The second connection portion 1420 may electrically connect the semiconductor element 1300 and the second substrate 1200 while bonding the semiconductor elements 1300 to the second substrate 1200.

The semiconductor package may include a third connection portion 1430 disposed on a lower surface of the first substrate 1100. The third connection portion 1430 may electrically connect the first substrate 1100 and the main board while bonding the first substrate 1100 to the main board.

In this case, the first connection portion 1410, the second connection portion 1420, and the third connection portion 1430 may electrically connect a plurality of components using at least one bonding method among wire bonding, solder bonding, and direct metal-to-metal bonding. That is, since the first connection portion 1410, the second connection portion 1420, and the third connection portion 1430 have a function of electrically connecting the plurality of components, when using direct metal-to-metal bonding, the semiconductor package may be understood as a part which is electrically connected, rather than a solder or wire.

The wire bonding method may mean electrically connecting a plurality of components using a conductor such as gold (Au) or the like. Further, the solder bonding method may electrically connect a plurality of components using a material containing at least one of Sn, Ag, and Cu. In addition, the direct metal-to-metal bonding method may mean directly bonding a plurality of components by applying heat and pressure between the plurality of components to recrystallize without the use of solder, a wire, a conductive adhesive, or the like. In addition, the direct metal-to-metal bonding method may mean a bonding method by the second connection portion 1420. In this case, the second connection portion 1420 may mean a solder layer formed between the plurality of components by recrystallization.

Specifically, the first connection portion 1410, the second connection portion 1420, and the third connection portion 1430 may bond the plurality of components to each other by a thermal compression bonding method. The thermal compression bonding method may mean a method of directly bonding the plurality of components by applying heat and pressure to the first connection portion 1410, the second connection portion 1420, and the third connection portion 1430.

In this case, on at least one of the first substrate 1100 and the second substrate 1200, the electrodes on which the first connection portion 1410, the second connection portion 1420, and the third connection portion 1430 are disposed may be provided with a protrusion protruding outward from an insulating layer of the corresponding substrate. The protrusion may protrude outward from the first substrate 1100 or the second substrate 1200.

The protrusion may be referred to as a bump. The protrusion may also be referred to as a post. The protrusion may also be referred to as a pillar. Preferably, the protrusion may refer to an electrode of the second substrate 1200 on which the second connection portion 1420 for bonding with the semiconductor element 1300 is disposed. That is, as a pitch of the terminals of the semiconductor element 1300 becomes finer, a short circuit may occur between the plurality of second connection portions 1420 each connected to a plurality of terminals of the semiconductor element 1300 by a conductive adhesive such as solder or the like. Accordingly, in the embodiment, thermal compression bonding may be performed to reduce the volume of the second connection portion 1420. Accordingly, the embodiment may include a protrusion on the electrodes of the second substrate 1200 on which the second connection portions 1420 are disposed to secure a degree of alignment, diffusion, and a diffusion-preventing property which prevents an intermetallic compound (IMC) formed between the conductive adhesive such as solder or the like and the protrusion from diffusing into the interposer and/or the substrate.

Further, referring to FIG. 18 further, the semiconductor package of the first embodiment may further include a connection member 1210.

The connection member 1210 may be referred to as a bridge substrate. For example, the connection member 1210 may include a redistribution layer. The connection member 1210 may function to horizontally electrically connect the plurality of semiconductor elements to each other. For example, since the area required for a semiconductor element is generally too large, the connection member 1210 may include the redistribution layer. Since semiconductor packages and semiconductor elements have large differences in the widths and depths of circuit patterns, a buffer function is required for the circuit pattern for electrical connection. The buffer function may mean having an intermediate size between the width or the like of the circuit pattern of the semiconductor package and the width or the like of the circuit pattern of the semiconductor element, and the redistribution layer may also include a buffer function.

In the embodiment, the connection member 1210 may be an organic bridge. For example, the connection member 1210 may contain an organic material. For example, the connection member 1210 may include an organic substrate containing an organic material instead of a silicon substrate. The connection member 1210 may be embedded in the second substrate 1200.

To this end, the second substrate 1200 may include a cavity, and the connection member 1210 may be disposed in the cavity of the second substrate 1200. The connection member 1210 may horizontally connect a plurality of semiconductor elements disposed on the second substrate 1200.

Referring to FIG. 19, the semiconductor package of the second embodiment may include a second substrate 1200 and a semiconductor element 1300. In this case, the semiconductor package of the second embodiment may have a structure in which the first substrate 1100 is omitted compared to the semiconductor package of the first embodiment.

That is, the second substrate 1200 of the second embodiment may function as a package substrate while functioning as an interposer.

A first connection portion 1410 disposed on a lower surface of the second substrate 1200 may couple the second substrate 1200 to a main board of an electronic device.

Referring to FIG. 20, the semiconductor package of the third embodiment may include a first substrate 1100 and a semiconductor element 1300.

In this case, the semiconductor package of the third embodiment may have a structure in which the second substrate 1200 is omitted compared to the semiconductor package of the first embodiment.

That is, the first substrate 1100 of the third embodiment may function to connect the semiconductor element 1300 to a main board while functioning as a package substrate. To this end, the first substrate 1100 may include a connection member 1110 for connecting a plurality of semiconductor elements. The connection member 1110 may be an organic bridge which connects the plurality of semiconductor elements.

Referring to FIG. 21, the semiconductor package of the fourth embodiment may further include a third semiconductor element 1330 compared to the semiconductor package of another embodiment. To this end, a fourth connection portion may be further disposed on one side of a first substrate 1100.

In this way, the semiconductor package of the fourth embodiment may have a structure in which semiconductor elements are mounted on each of upper and lower sides. In this case, the third semiconductor element 1330 may be a structure that is disposed on a lower surface of the second substrate 1200 in the above-described circuit board or semiconductor package.

Further, a connection member 1110 may be embedded in the first substrate 1100. The connection member 1110 may horizontally connect first and second semiconductor elements 1310 and 1320.

Further, the first substrate 1100 may include a conductive coupling portion 1450. The conductive coupling portion 1450 may further protrude from the first substrate 1100 toward the second semiconductor element 1320. The conductive coupling portion 1450 may be referred to as a bump, or alternatively, may be referred to as a post. The conductive coupling portion 1450 may be disposed with a protruding structure on an electrode disposed on the uppermost side of the first substrate 1100.

The third semiconductor element 1330 may be disposed on the conductive coupling portion 1450. In this case, the third semiconductor element 1330 may be connected to the first substrate 1100 through the conductive coupling portion 1450. Further, second connection portions 1420 may be disposed between the first and second semiconductor elements 1310 and 1320 and the third semiconductor element 1330.

Accordingly, the third semiconductor element 1330 may be electrically connected to the first and second semiconductor elements 1310 and 1320 through the second connection portions 1420.

That is, the third semiconductor element 1330 may be connected to the first and second semiconductor elements 1310 and 1320 through the second connection portions 1420 while being connected to the first substrate 1100 through the conductive coupling portion 1450.

In this case, the third semiconductor element 1330 may receive a power signal and/or power through the conductive coupling portion 1450. Further, the third semiconductor element 1330 may exchange communication signals with the first and second semiconductor elements 1310 and 1320 through the second connection portions 1420.

In the semiconductor package of the fourth embodiment, the power signal and/or power is supplied to the third semiconductor element 1330 through the conductive coupling portion 1450, thereby providing sufficient power for driving the third semiconductor element 1330 or allowing smooth control of power operation.

Accordingly, the embodiment may improve the driving characteristics of the third semiconductor element 1330. That is, the embodiment may address the problem of insufficient power provided to the third semiconductor element 1330. Furthermore, the embodiment may allow at least one of the power signal, power, and communication signal of the third semiconductor element 1330 to be provided through different paths through the conductive coupling portion 1450 and the second connection portions 1420. Accordingly, the embodiment may address the problem of communication signal loss due to the power signal. For example, the embodiment may minimize mutual interference between the communication signals and the power signals.

Meanwhile, the third semiconductor element 1330 of the fourth embodiment may have a POP structure in which a plurality of package substrates are stacked, and may be disposed on the first substrate 1100. For example, the third semiconductor element 1330 may be a memory package including a memory chip. Further, the memory package may be coupled to the conductive coupling portion 1450. In this case, the memory package may not be connected to the first and second semiconductor elements 1310 and 1320.

Furthermore, in the above-described example, a semiconductor package of a modified example may include a first substrate 1100 and first and second semiconductor elements 1310 and 1320 disposed on the first substrate 1100. Furthermore, the semiconductor package may include first connection portions 1410 disposed between the first substrate 1100 and the first and second semiconductor elements 1310 and 1320. That is, the semiconductor package may be a structure in which the second substrate and the second connection portion are omitted in the above-described example.

Meanwhile, when a circuit board having the above-described characteristics of the invention is used in IT devices or home appliances such as a smartphone, a server computer, a TV, and the like, it is possible to stably perform functions such as signal transmission, power supply, and the like. For example, when the circuit board having the characteristics of the present disclosure performs the semiconductor package function, it is possible to safely protect the semiconductor chip from external moisture or contaminants, and resolve the problem of a leakage current or an electrical short circuit between terminals or the problem of an open electrical circuit of the terminals supplied to the semiconductor chip. Further, when the circuit board performs signal transmission, it is possible to resolve noise problems. Accordingly, as the circuit board having the above-described characteristics of the invention may maintain stable functions of the IT devices or home appliances, the entire product and the circuit board to which the present disclosure is applied may achieve functional integrity or technical interoperability with each other.

When the circuit board having the above-described characteristics of the invention is used in a transportation device such as a vehicle or the like, it is possible to resolve the problem of distortion in signals transmitted to the transportation device, or further improve the stability of the transportation device by safely protecting the semiconductor chip controlling the transportation device from external sources and addressing the problem of a leakage current or an electrical short circuit between terminals or a problem of an open electrical circuit of the terminals supplied to the semiconductor chip. Accordingly, the transportation device and the circuit board to which the present disclosure is applied may achieve functional integrity or technical interoperability with each other.

An embodiment of the present disclosure provides a circuit board whose stress is relatively reduced even when having a certain thickness on an amorphous glass core layer by forming a core electrode portion having a high density of an orientation plane which significantly enhances a grain size without an additional insulating layer or adhesive layer between the glass core layer and the core electrode portion, and a semiconductor package including the same.

Further, the embodiment can provide a circuit board having large flexibility and reduced resistance and thus having improved mechanical and electrical reliability by having a large grain size and higher densities of (111) and (101) orientation planes than a (001) orientation plane, and a semiconductor package including the same.

In addition, the embodiment can provide a circuit board with relatively enhanced reliability of a glass substrate through stress relaxation by forming a core electrode portion on a glass core layer under different conditions from the formation of a build-up line portion to provide a core electrode portion having an orientation plane density and a grain size different from the build-up line portion, and a semiconductor package including the same.

Various and beneficial advantages and effects of the present disclosure are not limited to the above-described content, and will be more easily understood from the description of a specific embodiment of the present disclosure.

The features, structures, effects, and the like described above in the embodiments are included in at least one embodiment, and are not necessarily limited to one embodiment. Further, the features, structures, effects, and the like exemplified in each embodiment may also be combined or modified in other embodiments by those skilled in the art. Accordingly, it should be understood that the content related to such combinations and modifications are included in the scope of the embodiment.

Although the embodiments have been mainly described above, these are merely examples and are not intended to limit the embodiments, and those skilled in the art can appreciate that various modifications and applications not exemplified herein are possible without departing from the essential characteristics of the embodiments. For example, each of the components specifically shown in the embodiments may be modified. Further, it should be understood that differences related to the modifications and the applications are included in the scope of the embodiments defined by the appended claims.

What is claimed is:

1. A circuit board comprising:
a glass core layer;
a core electrode portion disposed on the glass core layer;
a build-up insulating portion disposed on the glass core layer; and
a build-up line portion disposed on the build-up insulating portion,
wherein the core electrode portion includes a first layer that is in contact with the glass core layer and a second layer disposed on the first layer, and
in the second layer, a density of a (111) plane is greater than a density of a (001) plane based on a plane perpendicular to a thickness direction.

2. The circuit board of claim 1, wherein the first layer contains a metal oxide.

3. The circuit board of claim 1, wherein a thickness of the first layer is smaller than a thickness of the second layer.

4. The circuit board of claim 1, wherein, in the second layer, a density of a (101) plane is greater than the density of the (001) plane based on the plane perpendicular to the thickness direction.

5. The circuit board of claim 1, wherein a density of the (111) plane based on a plane perpendicular to a thickness direction of the build-up line portion is less than the density of the (111) plane based on the plane perpendicular to the thickness direction of the second layer.

6. The circuit board of claim 1, wherein a density of a (101) plane based on a plane perpendicular to a thickness direction of the build-up line portion is less than a density of the (101) plane based on the plane perpendicular to the thickness direction of the second layer.

7. The circuit board of claim 1, wherein a density of the (001) plane based on a plane perpendicular to a thickness direction of the build-up line portion is greater than the density of the (001) plane based on the plane perpendicular to the thickness direction of the second layer.

8. The circuit board of claim 1, wherein an average grain size of the build-up line portion is smaller than an average grain size of the second layer.

9. The circuit board of claim 1, wherein an average grain size of the second layer is greater than 1.9 μm.

10. The circuit board of claim 1, wherein the core electrode portion includes a core line portion disposed on an upper surface and a lower surface of the glass core layer and a core via electrode passing through the glass core layer.
